(19) United States
(12) Patent Application Publication
(10) Pub. No.: US 2026/0370224 A1
(43) Pub. Date: Nov. 19, 2026

(54) Decoupling capacitor circuit capable of preventing noise interference

(71) Applicant: NOVATEK Microelectronics Corp., Hsin-Chu (TW)

(72) Inventors: Long-Yi Lin, Taipei City (TW); Jen-Hao Liao, Hsinchu County (TW)

(73) Assignee: NOVATEK Microelectronics Corp., Hsin-Chu (TW)

(21) Appl. No.: 19/209,727

(22) Filed: May 15, 2025

(51) Int. Cl. H03K 17/687; G05F 1/10

(52) U.S. Cl. CPC H03K 17/6871; G05F 1/10

(57) ABSTRACT

A decoupling capacitor circuit, for power line and ground line, includes first transistor, comprising first drain, first gate and first source; second transistor, comprising second drain, second gate and second source, wherein the first gate and the second drain are coupled to first internal node, the first drain and the second gate are coupled to second internal node, the first source is coupled to the power line, and the second source is coupled to the ground line; and third transistor, comprising third drain, third gate and third source, wherein the third drain and the third source are coupled to the power line and the third gate is coupled to the first internal node; and fourth transistor, comprising fourth drain, fourth gate and fourth source, wherein the fourth drain and the fourth gate are coupled to the second internal node and the fourth source is coupled to the power line.

### BACKGROUND OF THE INVENTION

### 1. Field of the Invention

The present invention relates to a decoupling capacitor circuit, and more specifically, to a decoupling capacitor circuit having various clamping circuits to clamp voltages of internal nodes.

### 2. Description of the Prior Art

In high-speed digital circuits, a large number of decoupling capacitors implemented with metal-oxide-semiconductor field-effect capacitors (MOSCAPs) are usually placed between the power line and the ground line. Decoupling capacitors may reduce the power noise caused by the instantaneous load current on the power line to achieve voltage stabilization and improve the performance of high-speed digital circuits.

However, when using MOSCAP as a decoupling capacitor in advanced manufacturing processes, the gate of MOSCAP may encounter the problem of being penetrated by electrostatic discharge current (ESD current, or IESD). As P-type MOSCAP (PMOSCAP) as an example, since the drain and source of PMOSCAP are connected to the power line and the gate of PMOSCAP is connected to the ground line, the ESD current may penetrate through the gate and form a current loop flowing from the power line through the ground line, thereby putting the gate at risk of electrostatic discharge damage. Thus, how to prevent the decoupling capacitor implemented with MOSCAP from being damaged by electrostatic discharge has become one of the issues of in the industry.

### SUMMARY OF THE INVENTION

It is therefore an objective of the present invention to provide various decoupling capacitor circuits, so as to prevent the decoupling capacitor implemented with MOSCAP from being damaged by electrostatic discharge has become one of the issues in the industry.

An embodiment of the present invention discloses a decoupling capacitor circuit, for a power line and a ground line, includes a first internal node; a second internal node; a first transistor, comprising a first drain, a first gate and a first source; a second transistor, comprising a second drain, a second gate and a second source, wherein the first gate and the second drain are coupled to the first internal node, the first drain and the second gate are coupled to the second internal node, the first source is coupled to the power line, and the second source is coupled to the ground line; and a third transistor, comprising a third drain, a third gate and a third source, wherein the third drain and the third source are coupled to the power line and the third gate is coupled to the first internal node; and a fourth transistor, comprising a fourth drain, a fourth gate and a fourth source, wherein the fourth drain and the fourth gate are coupled to the second internal node and the fourth source is coupled to the power line.

An embodiment of the present invention discloses a decoupling capacitor circuit, for a power line and a ground line, includes a first internal node; a second internal node; a first transistor, comprising a first drain, a first gate and a first source; a second transistor, comprising a second drain, a second gate and a second source, wherein the first gate and the second drain are coupled to the first internal node, the first drain and the second gate are coupled to the second internal node, the first source is coupled to the power line, and the second source is coupled to the ground line; and a third transistor, comprising a third drain, a third gate and a third source, wherein the third drain and the third source are coupled to the power line and the third gate is coupled to the first internal node; and a first diode, having a first anode coupled to the first internal node and a first cathode coupled to the ground line.

An embodiment of the present invention discloses a decoupling capacitor circuit, for a power line and a ground line, includes a first internal node; a second internal node; a first transistor, comprising a first drain, a first gate and a first source; a second transistor, comprising a second drain, a second gate and a second source, wherein the first gate and the second drain are coupled to the first internal node, the first drain and the second gate are coupled to the second internal node, the first source is coupled to the power line, and the second source is coupled to the ground line; and a third transistor, comprising a third drain, a third gate and a third source, wherein the third drain and the third source are coupled to the power line and the third gate is coupled to the first internal node; and a first resistor, coupled between the first internal node and the ground line.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a decoupling capacitor circuit according to an embodiment of the present invention.

FIG. 2 is a schematic diagram of a decoupling capacitor circuit according to another embodiment of the present invention.

FIG. 3 is a schematic diagram of a decoupling capacitor circuit according to another embodiment of the present invention.

FIG. 4 is a schematic diagram of a decoupling capacitor circuit according to another embodiment of the present invention.

FIG. 5 is a schematic diagram of a decoupling capacitor circuit according to another embodiment of the present invention.

FIG. 6 is a schematic diagram of a decoupling capacitor circuit according to another embodiment of the present invention.

FIG. 7 is a schematic diagram of a decoupling capacitor circuit according to another embodiment of the present invention.

FIG. 8 is a schematic diagram of a decoupling capacitor circuit according to another embodiment of the present invention.

FIG. 9 is a schematic diagram of a decoupling capacitor circuit according to another embodiment of the present invention.

FIG. 10 is a schematic diagram of a decoupling capacitor circuit according to another embodiment of the present invention.

FIG. 11 is a schematic diagram of a decoupling capacitor circuit according to another embodiment of the present invention.

FIG. 12 is a schematic diagram of a decoupling capacitor circuit according to another embodiment of the present invention.

FIG. 13 is a schematic diagram of a decoupling capacitor circuit according to another embodiment of the present invention.

### DETAILED DESCRIPTION

Certain terms are used throughout the description and following claims to refer to specific components. As one skilled in the art will appreciate, hardware manufacturers may refer to a component by different names. This document does not intend to distinguish between components that differ in name but not function. In the following description and in the claims, the terms “include” and “comprise” are utilized in an open-ended fashion, and thus should be interpreted to mean “include, but not limited to”. Also, the term “couple” is intended to mean either an indirect or direct electrical connection. Accordingly, if one device is coupled to another device, that connection may be through a direct electrical connection, or through an indirect electrical connection via other devices and connections.

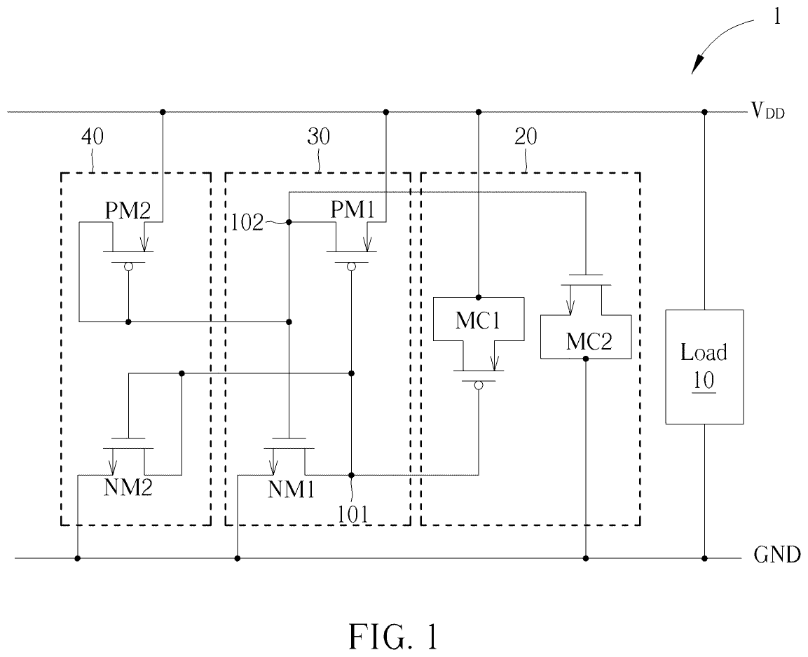

Please refer to FIG. 1. FIG. 1 is a schematic diagram of a decoupling capacitor circuit 1 according to an embodiment of the present invention. The decoupling capacitive circuit 1 includes a first metal-oxide-semiconductor field-effect transistor (MOSFET) PM1, a second MOSFET NM1, a third MOSFET MC1, a fourth MOSFET MC2, a fifth MOSFET PM2, and a sixth MOSFET NM2. Specifically, the third MOSFET MC1 and the fourth MOSFET MC2 are configured as a decoupling capacitor 20 coupled between a power line V_{DD} and a ground line GND. The decoupling capacitor 20 may reduce the power noise caused by the instantaneous current draw on the power line V_{DD} for a load 10 coupled between the power line V_{DD} and the ground line GND, so that the decoupling capacitor 20 may achieve the purpose of voltage stabilization and enhance the performance of the load 10. It should be noted that the load 10 may be a high-speed digital circuit, but not limited thereto.

Furthermore, the first MOSFET PM1 and the second MOSFET NM1 are configured as an ESD protection circuit 30 coupled to the decoupling capacitor 20, so that the gates of the third MOSFET MC1 and the fourth MOSFET MC2 are not directly connected to the ground line GND and the power line V_{DD}. In this way, the ESD protection circuit 30 prevents the ESD current from penetrating the gates of the third MOSFET MC1 and the fourth MOSFET MC2. In detail, the source of the first MOSFET PM1 is coupled to the power line V_{DD}, the source of the second MOSFET NM1 is coupled to the ground line GND, the gate of the first MOSFET PM1 and the drain of the second MOSFET NM1 are coupled to a low voltage node 101, the drain of the first MOSFET PM1 and the gate of the second MOSFET NM1 are coupled to a high voltage node 102, the drain and the source of the third MOSFET MC1 are coupled to the power line V_{DD}, the gate of the third MOSFET MC1 is coupled to the low voltage node 101, the drain and the source of the fourth MOSFET MC2 are coupled to the ground line GND, and the gate of the fourth MOSFET MC2 is coupled to the high voltage node 102. In this way, the gate of the third MOSFET MC1 will not be directly connected to ground GND and the gate of the fourth MOSFET MC2 will not be directly connected to the power line V_{DD}. Therefore, the ESD current will not penetrate through the gate of the third MOSFET MC1 and the gate of the fourth MOSFET MC2; that is, the risk of gate breakdown of the third MOSFET MC1 and the fourth MOSFET MC2 is avoided.

It should be noted that the first MOSFET PM1 and the second MOSFET NM1 in the ESD circuit 30 are connected in a latch structure. When the power line V_{DD} is powered on, the voltages of the high voltage node 102 and the low voltage node 101 rise synchronously. Subsequently, the voltages of the high voltage node 102 and the low voltage node 101 are greater than the threshold voltages of the first MOSFET PM1 and the second MOSFET NM1, so that after the first MOSFET PM1 and the second MOSFET NM1 are turned on, the voltage of the high voltage node 102 continues to rise to a voltage close to the power line V_{DD}, and the voltage of the low voltage node 101 decreases to a voltage close to the ground line V_{DD}. However, the latch structure of the first MOSFET PM1 and the second MOSFET NM1 may have another stable state in which the voltage of the high voltage node 102 approaches the voltage of the ground line GND and the voltage of the low voltage node 101 approaches to a voltage close to the voltage of the power line V_{DD}. In this circumstance, the gate of the third MOSFET MC1 is at a high voltage and the gate of the fourth MOSFET MC2 is at a low voltage, such that the third MOSFET MC1 and the fourth MOSFET MC2 are not able to provide capacitance values. Therefore, the fifth MOSFET PM2 and the sixth MOSFET NM2 are configured as a clamping circuit 40 coupled to the ESD protection circuit 30 to clamp the latch structure of the first MOSFET PM1 and the second MOSFET NM1 in a properly stable state. In detail, the source of the fifth MOSFET PM2 is coupled to the power line V_{DD}, the drain and the gate of the fifth MOSFET PM2 are coupled to the high voltage node 102, the source of the sixth MOSFET NM2 is coupled to the ground line GND, and the drain and the gate of the sixth MOSFET NM2 are coupled to the low voltage node 101. In other words, the fifth MOSFET PM2 and the sixth MOSFET NM2 are connected in a diode-connected structure. In this way, when the cross-voltage of the fifth MOSFET PM2 is greater than a threshold voltage, the fifth MOSFET PM2 will micro-conduct, so that the voltage of the high voltage node 102 is charged to a voltage close to the voltage of the power line V_{DD}. Similarly, when the cross-voltage of the sixth MOSFET NM2 is greater than the threshold voltage, the sixth MOSFET NM2 will micro-conduct so that the voltage of the low voltage node 101 is discharged to a voltage close to the ground GND. In other words, the fifth MOSFET PM2 and the sixth MOSFET NM2 may clamp the latch structures of the first MOSFET PM1 and the second MOSFET NM1 to a properly stable state. In this way, the gate of the third MOSFET MC1 is not directly connected to the ground line GND, and the gate of the fourth MOSFET MC2 is not directly connected to the power line V_{DD}. Therefore, the ESD current will not penetrate through the gate of the third MOSFET MC1 and the gate of the fourth MOSFET MC2; that is, the risk of gate breakdown of the third MOSFET MC1 and the fourth MOSFET MC2 is avoided.

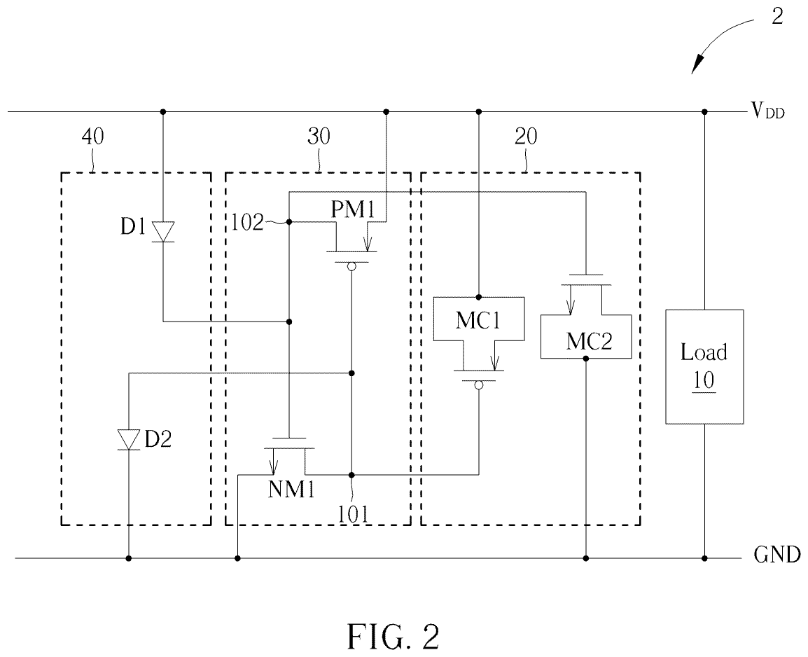

It should be noted that any circuit which achieves the clamping of the voltages at the low voltage node 101 and the high voltage node 102 may be used to realize the clamping circuit 40. It should be noted that the following decoupling capacitor circuits are derived from the decoupling capacitor circuit 1, and therefore, the same components are presented by the same symbols. For example, please refer to FIG. 2. FIG. 2 is a schematic diagram of a decoupling capacitor circuit 2 according to another embodiment of the present invention. In this embodiment, the clamping circuit 40 includes a first diode D1 and a second diode D2. In detail, the anode of the first diode D1 is coupled to the power line V_{DD}, the cathode of the first diode D1 is coupled to the high voltage node 102, the anode of the second diode D2 is coupled to the low voltage node 101, and the cathode of the second diode D2 is coupled to the ground line GND. Specifically, when the cross-voltage of the first diode Dl is greater than a threshold voltage, the first diode D1 turns on so that the voltage of the high voltage node 102 is charged to a voltage close to the voltage of the power line V_{DD}. Similarly, when the cross-voltage of the second diode D2 is greater than the threshold voltage, the second diode D2 turns on so that the voltage of the low voltage node 101 is discharged to a voltage close to the ground GND. In this way, the gate of the third MOSFET MC1 is not directly connected to the ground line GND and the gate of the fourth MOSFET MC2 is not directly connected to the power line V_{DD}. Therefore, the ESD current will not penetrate through the gate of the third MOSFET MC1 and the gate of the fourth MOSFET MC2; that is, the risk of gate breakdown of the third MOSFET MC1 and the fourth MOSFET MC2 is avoided.

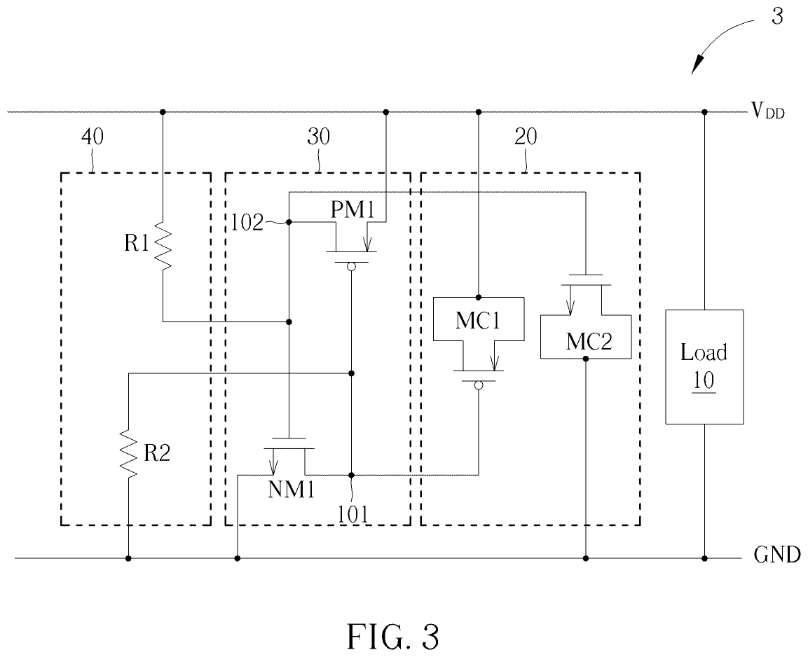

For example, please refer to FIG. 3. FIG. 3 is a schematic diagram of a decoupling capacitor circuit 3 according to another embodiment of the present invention. In this embodiment, the clamping circuit 40 includes a first resistor R1 and a second resistor R2. The first resistor R1 is coupled to the high voltage node 102 such that the voltage of the high voltage node 102 is charged to a voltage close to the power line V_{DD}. The second resistor R2 is coupled to the low voltage node 101 so that the voltage of the low voltage node 101 is discharged to a voltage close to the ground GND. In this way, the gate of the third MOSFET MC1 is not directly connected to the ground GND, and the gate of the fourth MOSFET MC2 is not directly connected to the power line V_{DD}. Therefore, the ESD current will not penetrate through the gate of the third MOSFET MC1 and the gate of the fourth MOSFET MC2; that is, the risk of gate breakdown of the third MOSFET MC1 and the fourth MOSFET MC2 is avoided.

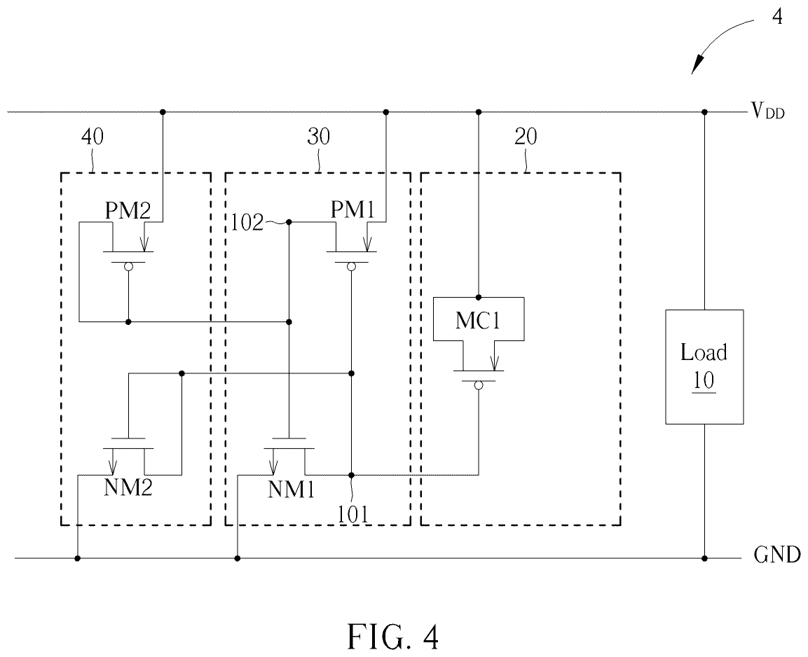

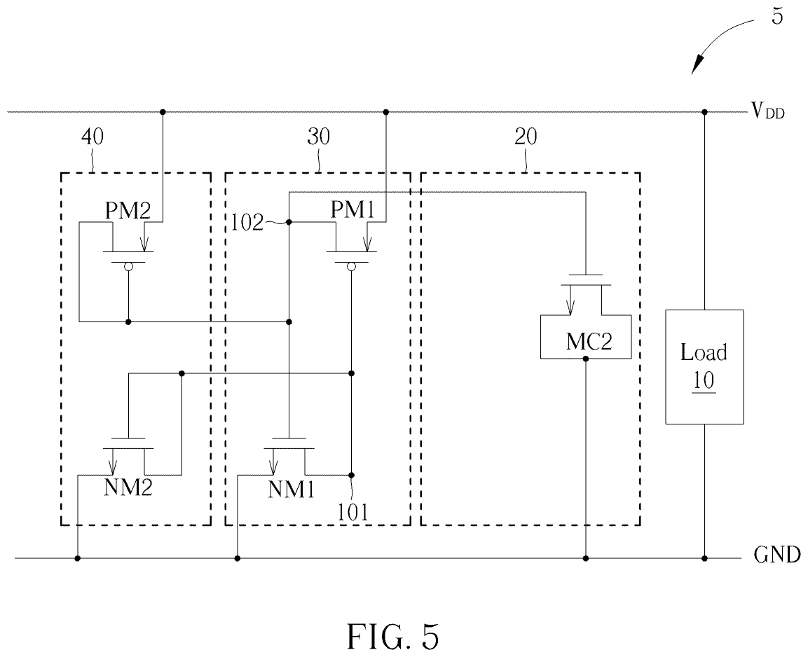

It should be noted that the decoupling capacitance 20 in the decoupling capacitance circuit 1, the decoupling capacitance circuit 2 and the decoupling capacitance circuit 3 may be realized by only one of the third MOSFET MC1 and the fourth MOSFET MC2. For example, please refer to FIG. 4 and FIG. 5. FIG. 4 and FIG. 5 are schematic diagrams of a decoupling charge capacitor circuit 4 and a decoupling charge capacitor circuit 5 according to embodiments of the present invention. The decoupling capacitor circuit 4 and the decoupling capacitor circuit 5 are derived from the decoupling capacitor circuit 1, and therefore, detailed descriptions of the decoupling capacitor circuit 4 and the decoupling capacitor circuit 5 and their derivatives may be found in the previous description at and will not be repeated herein.

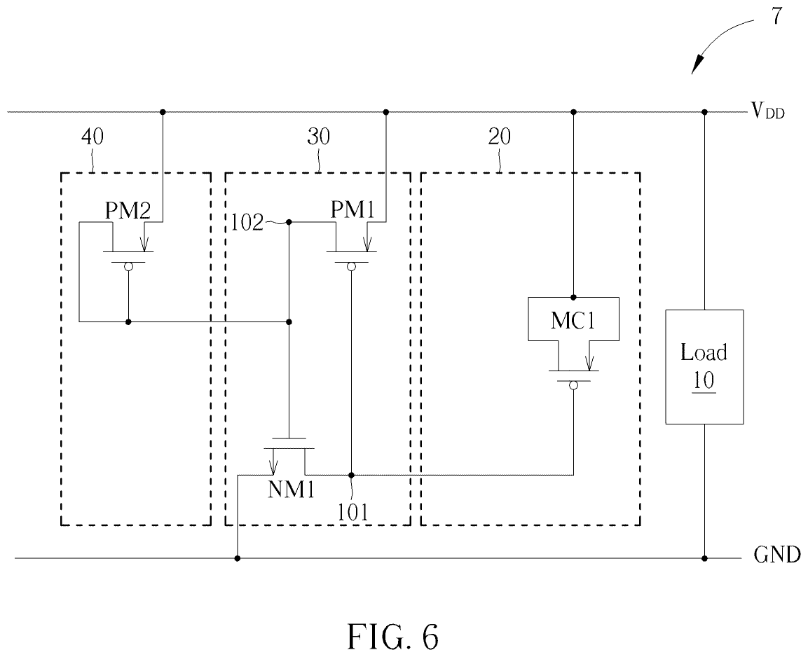

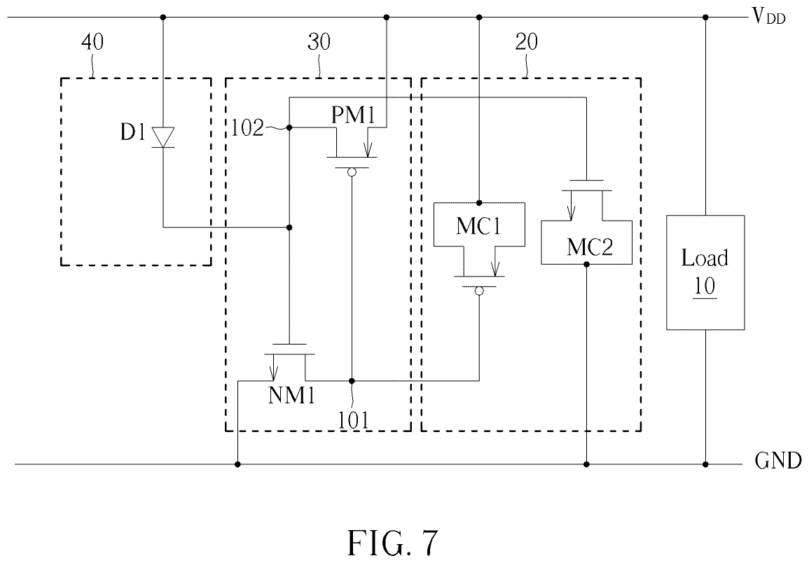

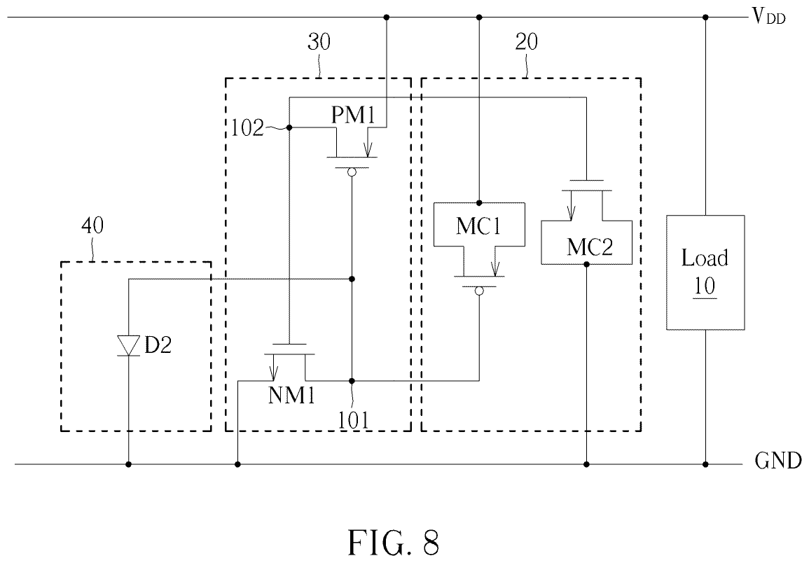

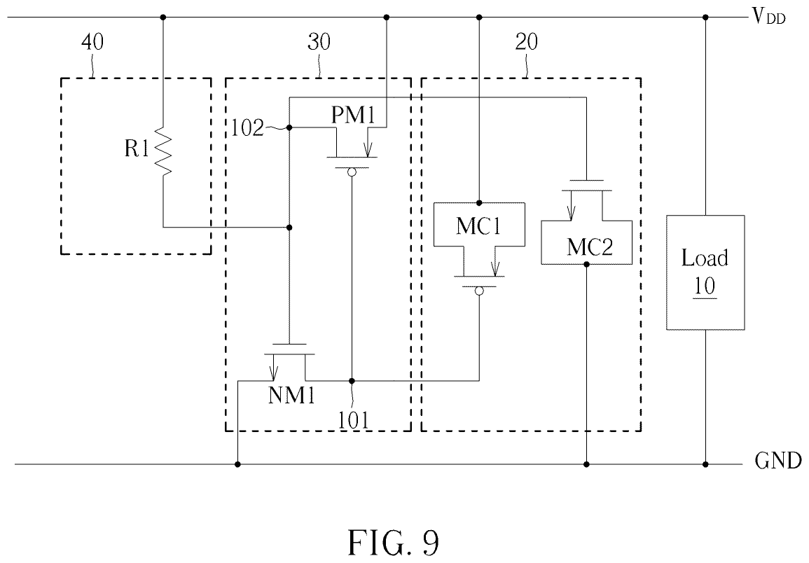

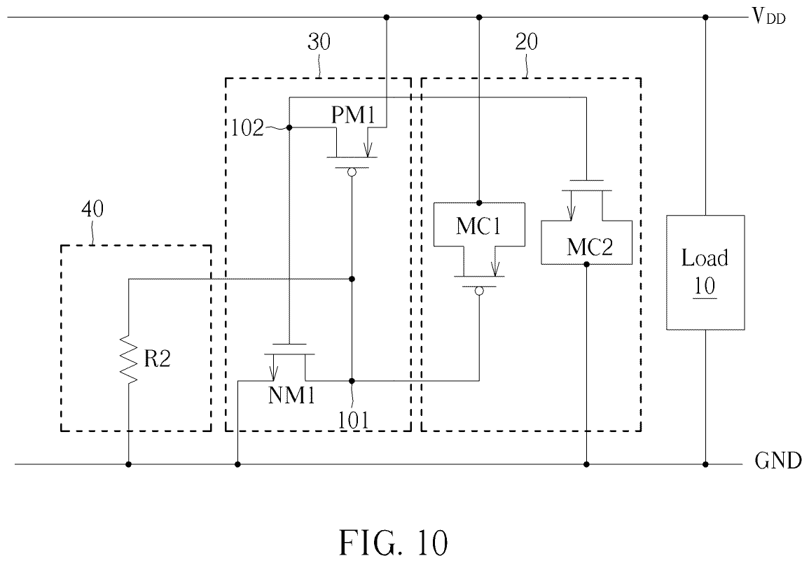

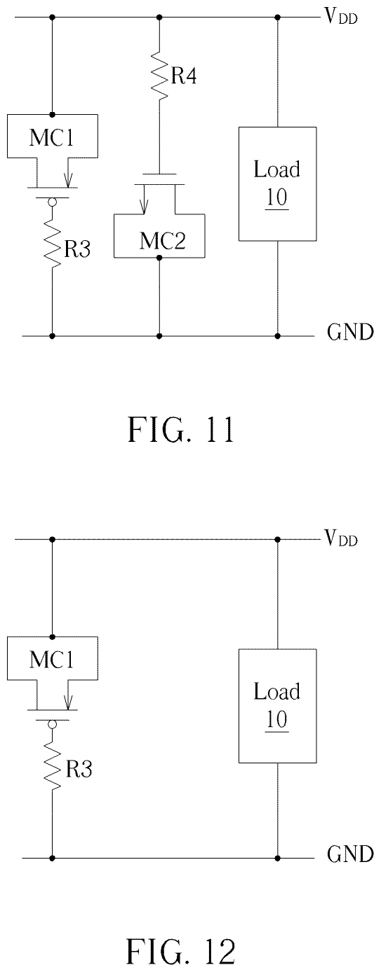

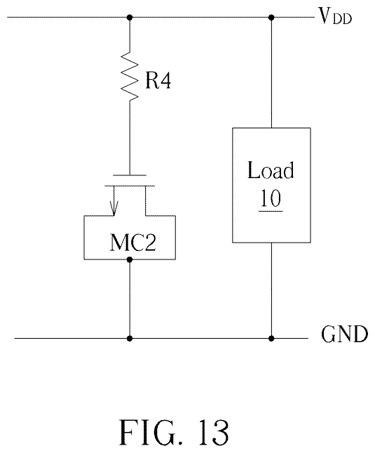

Furthermore, since the first MOSFET PM1 and the second MOSFET NM1 in the ESD circuit 30 are connected in a latch structure, as long as the clamping circuit 40 clamps the voltage of the high voltage node 102 in the ESD circuit 30 to a voltage close to the power line V_{DD}, the low voltage node 101 is latched to a voltage close to the ground line GND. Alternatively, as long as the clamping circuit 40 clamps the voltage of the low voltage node 101 in the ESD circuit 30 to a voltage close to the ground GND, the high voltage node 102 is latched to a voltage close to the power line V_{DD}. For example, please refer to FIG. 6. FIG. 6 is schematic diagram of a decoupling capacitor circuit 6 according to an embodiment of the invention. Specifically, the clamping circuit 40 in the decoupling capacitor circuit 6 includes only the fifth MOSFET PM2. The decoupling capacitor circuit 6 is derived from the decoupling capacitor circuit 4. Therefore, the detailed description and derivative changes of the decoupling capacitor circuit 6 is described as above, and will not be repeated here. It should be noted that the decoupling capacitor circuits 1 to 7 are different embodiments of the present invention. Those skilled in the art should readily make combinations, modifications and/or alterations on the abovementioned description and examples. For example, as shown in FIG. 7 and FIG. 8, the decoupling capacitor circuit 2 may include only the first diode D1 or the second diode D2. Alternatively, as shown in FIG. 9 and FIG. 10, the decoupling capacitor circuit 3 may include only the first resistor R1 or the second resistor R2, but not limited thereto. In addition, please refer to FIGS. 11 to 13. The decoupling capacitor circuit of the present invention may utilize the resistors R3 and R4 to be connected in series with the third MOSFET MC1 and the fourth MOSFET MC2, respectively, to prevent the third MOSFET MC1 and the fourth MOSFET MC2 from being broken through by ESD current. In this way, the decoupling capacitor 20 may achieve the purpose of voltage stabilization and improve the performance of the load 10.

In summary, the decoupling capacitor circuit of the present invention prevents the gate of the MOSFET, which is used as the decoupling capacitor, from being penetrated by the ESD current, and reduces the power noise caused by the instantaneous current drawn from the power line to the load coupled between the power line and the ground line, so that the decoupling capacitor achieves the goal of stabilizing the voltage and enhancing the performance of the load.

Those skilled in the art will readily observe that numerous modifications and alterations of the device and method may be made while retaining the teachings of the invention. Accordingly, the above disclosure should be construed as limited only by the metes and bounds of the appended claims.

1. A decoupling capacitor circuit, for a power line and a ground line, comprising:
a first internal node;
a second internal node;
a first transistor, comprising a first drain, a first gate and a first source;
a second transistor, comprising a second drain, a second gate and a second source, wherein the first gate and the second drain are coupled to the first internal node, the first drain and the second gate are coupled to the second internal node, the first source is coupled to the power line, and the second source is coupled to the ground line; and
a third transistor, comprising a third drain, a third gate and a third source, wherein the third drain and the third source are coupled to the power line and the third gate is coupled to the first internal node; and
a fourth transistor, comprising a fourth drain, a fourth gate and a fourth source, wherein the fourth drain and the fourth gate are coupled to the second internal node and the fourth source is coupled to the power line.

2. The decoupling capacitor circuit of claim 1, further comprising:
a fifth transistor, comprising a fifth drain, a fifth gate and a fifth source, wherein the fifth drain and the fifth source are coupled to the ground line and the fifth gate is coupled to the second internal node.

3. The decoupling capacitor circuit of claim 2, further comprising:
a sixth transistor, comprising a sixth drain, a sixth gate and a sixth source, wherein the sixth drain and the sixth gate are coupled to the first internal node and the sixth source is coupled to the ground line.

4. The decoupling capacitor circuit of claim 1, further comprising:
a fifth transistor, comprising a fifth drain, a fifth gate and a fifth source, wherein the fifth drain and the fifth gate are coupled to the first internal node and the fifth source is coupled to the ground line.

5. A decoupling capacitor circuit, for a power line and a ground line, comprising:
a first internal node;
a second internal node;
a first transistor, comprising a first drain, a first gate and a first source;
a second transistor, comprising a second drain, a second gate and a second source, wherein the first gate and the second drain are coupled to the first internal node, the first drain and the second gate are coupled to the second internal node, the first source is coupled to the power line, and the second source is coupled to the ground line; and
a third transistor, comprising a third drain, a third gate and a third source, wherein the third drain and the third source are coupled to the power line and the third gate is coupled to the first internal node; and
a first diode, having a first anode coupled to the first internal node and a first cathode coupled to the ground line.

6. The decoupling capacitor circuit of claim 5, further comprising:
a fourth transistor, comprising a fourth drain, a fourth gate and a fourth source, wherein the fourth drain and the fourth source are coupled to the ground line and the fourth gate is coupled to the second internal node.

7. The decoupling capacitor circuit of claim 6, further comprising:
a second diode, having a second anode coupled to the power line and a second cathode coupled to the second internal node.

8. The decoupling capacitor circuit of claim 5, further comprising:
a second diode, having a second anode coupled to the power line and a second cathode coupled to the second internal node.

9. A decoupling capacitor circuit, for a power line and a ground line, comprising:
a first internal node;
a second internal node;
a first transistor, comprising a first drain, a first gate and a first source;
a second transistor, comprising a second drain, a second gate and a second source, wherein the first gate and the second drain are coupled to the first internal node, the first drain and the second gate are coupled to the second internal node, the first source is coupled to the power line, and the second source is coupled to the ground line; and
a third transistor, comprising a third drain, a third gate and a third source, wherein the third drain and the third source are coupled to the power line and the third gate is coupled to the first internal node; and
a first resistor, coupled between the first internal node and the ground line.

10. The decoupling capacitor circuit of claim 9, further comprising:
a fourth transistor, comprising a fourth drain, a fourth gate and a fourth source, wherein the fourth drain and the fourth source are coupled to the ground line and the fourth gate is coupled to the second internal node.

11. The decoupling capacitor circuit of claim 10, further comprising:
a second resistor, coupled between the power line and the second internal node.

12. The decoupling capacitor circuit of claim 9, further comprising:
a second resistor, coupled between the power line and the second internal node.
